(19) United States
(12) Patent Application Publication
(10) Pub. No.: US 2013/0032196 A1
(43) Pub. Date: Feb. 7, 2013

(54) METHOD AND APPARATUS FOR DISTRIBUTED TRACKING SOLAR COLLECTOR

(71) Applicant: Dipankar, Mumbia (IN)

(72) Inventor: Dipankar, Mumbia (IN)

(73) Assignee: Treelabs Foundation

(21) Appl. No.: 13/570,967

(22) Filed: Aug. 9, 2012

Related U.S. Application Data
(63) Continuation-in-part of application No. PCT/IN2011/000089, filed on Feb. 9, 2011.

(30) Foreign Application Priority Data
Feb. 10, 2010 (IN) 364/MUM/2010

(51) Int. Cl. F24J 2/38; G01J 1/44; G01C 9/00; H01L 31/052

(52) U.S. Cl. 136/246; 126/574; 250/203.4; 33/301

(57) ABSTRACT

A system is disclosed, consisting of scalable array of distributed and networked control systems such as small heliostats, and orthogonal trackers capable of precise sun-position measurements, directing incident solar radiation to one or more predetermined targets. A method for implementing a scalable heliostat array for use in solar-energy applications, telescopy, etc., is also disclosed.

### CROSS REFERENCE TO RELATED APPLICATION

This application is a continuation-in-part of International Patent Application No. PCT/IN2011/000089 filed Feb. 9, 2011, which in turn claims the benefit of Indian Patent Application Number 364/MUM/2010, filed Feb. 10, 2010. The entire contents of each of the foregoing applications are incorporated herein by reference.

### BACKGROUND OF THE INVENTION

This application generally relates to methods and apparatus to implement a large and scalable array of distributed control systems, such as small heliostats in solar energy harnessing, and other areas. More specifically the embodiments herein relate to a master-slave topology of orthogonal-tracker(s) and small reflectors to automatically track the Sun accurately and direct its reflected beam to specified targets.

In general, solar energy harnessing addresses two broad areas a) Solar-PV (Photovoltaic) and b) Solar-Thermal. The efficiency of energy harnessing depends significantly on how accurately one can follow the Sun. This is called Solar-Tracking. The device to effect solar-tracking is called a ‘Heliostat’. Even for a flat surface, the difference in energy collection between optimized no-tracking and accurate tracking can be as high as 40%. Many other applications, such as Solar Tower Power, will simply not work without solar-tracking. Therefore, there is considerable commercial interest to find accurate, reliable, scalable and cost effective means to track the Sun.

In Solar-PV systems, the collector surface of interest is a panel of solar-cells, which is oriented to intercept maximum amount of solar radiation. The energy receiving surface has to ‘look’ at Sun directly (orthogonally). Small orientation errors (1-2 degrees) do not seriously impact energy collection in Solar-PV. The need here is to create inexpensive, robust and energy-lean heliostats that can orient Solar-PV panels. This is a challenge that has not yet been satisfactorily solved in prior art.

In Solar-Thermal systems, the panel is usually a reflector or mirror. The panel is continuously re-oriented so that reflected sunlight is appropriately directed to a receiver or collector. The accuracy requirements are far more stringent, as compared to Solar-PV. For example, a 1 m² reflected beam subtends an angle of 0.01 radians to a target 100 m away. So the accuracy of orientation must be greater than 0.001 radians (or 0.05 degrees), and often a higher degree of accuracy is necessary. Spillage loss (radiation not reaching target) increases as the square of pointing inaccuracy. According to a Sandia National Laboratory report, a reduction in tracking error by a few milli-radians may reduce the cost of a Solar Tower Power plant by as much as 5%. So, accurate tracking is very important.

Prior art Solar-Thermal schemes that desire high reflecting accuracy need to know sun-position accurately. Sophisticated and comprehensive formulae known from the field of astronomy are used to predict the position of astronomical objects (Reference: “Astronomical Algorithms”—Jean Meeus, 1991). Earth has a complex trajectory around the Sun. The position of Sun as seen from any specified location on Earth, depends on many factors. Rotation of Earth, revolution of Earth about the Sun, precession of Earth's axis, perturbations due to Moon, Mars and other planets, refraction through atmosphere, and many more factors need to be taken into account to determine effective sun-position accurately. Based on these astronomical calculations the work done at NREL (“Solar position algorithms for solar radiation applications”—Ibrahim Reda and Afshin Andreas, NREL, 2005) attempts to predict solar position.

Prior art as in patent WO-055,624-A1 (“Calibration and tracking control of heliostats in a central tower receiver solar power plant”, Reznik et. al, Apr. 30, 2009), uses solar-position algorithms developed by NREL. Solar-position information based on calculations are essentially open-loop. Calculations based on models of physical systems, however accurate, are still an approximation of reality.

It is easy to see that open-loop calculations may not provide accurate solar-position. Such formulae may be relatively accurate for use on clear nights when telescopes may be used. The presence of Sun's heat during day-time causes unpredictable atmospheric turbulence and refractive index changes. Variations in temperature, pressure and moisture content would cause Sun's rays to refract and therefore deviate from astronomical predictions by up to fractions of a degree. In fact it is well known (see for example the article on atmospheric refraction: en.wikipedia.org/wiki/Atmospheric_refraction), that even predicting standard Sunrise and Sunsets with accuracies of more than one min (equivalent to 0.25 degrees) is meaningless, due to daily variations of temperature and pressure. The substantial bending of light due to refractive index changes of the atmosphere is amply convincing when any one observes a mirage (en.wikipedia.org/wiki/Mirage). Thus schemes based on open-loop solar-tracking algorithms will suffer from random inaccuracies.

The references U.S. Pub. No. 2011/0000478A1 (“Camera based heliostat-tracking controller”, Reznik et. al, Jan. 6, 2011), U.S. Pub. No. 2008/0236568A1 (“Heliostat with integrated image-based tracking controller”, Hickerson et. al, Oct. 2, 2008) and U.S. Pub. No. 2009/0249787A1 (“Method for controlling the alignment of a heliostat with respect to a receiver, heliostat device and solar power plant”, Pfahl et. al, Oct. 8, 2009) tries to specifically address the issue of overcoming pointing errors in heliostats. However, the indicated methods are not sufficiently convincing to yield accurate results. The central technique suggested in these patents rely on trying to find the bisector of the angle between Sun and target images. Trying to simultaneously image the Sun and target, with very large differences in absolute brightness levels is not trivial. Also, one has to use wide-angle optics, to ensure that one is able to view both the Sun and target even when they are widely separated (greater than 90 degrees). Wide-angle optics, apart from being more expensive, are also prone to distortions which could adversely affect the control systems that are based on imaging. Furthermore, trying to perform complex image-processing in-situ and in real-time would require superior hardware, and therefore enhanced cost and power requirement.

Another equally important factor, related to accurate tracking, is to determine the location/orientation of the target(s), from the point of view of each heliostat in a distributed array. Each element must also have mechanisms to re-calibrate, should any change take place, intended or unintended. Once again, many of the issues related to target determination, including multiple targets and variable targets, have been only partially solved in prior art.

Furthermore, accuracy and integrity of electrical/electronics and mechanical components such as gears, screws, cams, sensors, etc., and their long-term reliability in the field in the presence of natural elements such as rain, dust, insects, etc., play equally important roles. Thus, even if one were to have accurate information of the Sun and also the target, but have hardware that is imprecise, and therefore unable to implement the desired accuracy, one would still have pointing errors. Prior art tried to address many such issues, albeit in piece-meal fashion, and without consideration of the entire system, including cost considerations. Usually, one makes compromises based on cost and performance in prior art. The international market estimates that target price for reliable heliostats at present (2011) should be at most US$80-100/m² or even lower, and this is by and large unfulfilled in prior art.

Operation of heliostats and their associated control systems themselves require power. If the systems available rely on auxiliary power, then it is an added constraint. It also imposes cost and reliability barrier towards implementing truly distributed systems. Ideally heliostat control systems should be implemented to operate on very low power, which may be derived from tiny on-board solar-PV panels. This is not adequately solved in prior art.

Conventional large heliostat systems such as ones described in U.S. Pat. No. 6,336,452-B1 (“Solar powered fluid heating system”, Tommy Lee Tirey, Jan. 8, 2002) or Indian patent 207761 (“Concentrating solar collector system for thermal and/or electrical power generation”, Shireesh Kedare, Aug. 10, 2007) with reflector sizes in the range of 10 m×10 m require the supporting heliostat to have strong ground foundation and require good land commitment. Also it needs external control system that will require power (up to 500 W) and instructions from a control room. A conventional system cannot be scaled up incrementally. Each unit may be of 100 m² capacity and is not easy to deploy since conventional large structures are fabricated in workshops based on individual requirement or turnkey projects. Such systems are also difficult to transport to remote places owing to the large structural make up. Further for such conventional heliostat maximum operable temperature is limited to working fluid which is typically not more than 200 degree C. The conventional systems are mostly deployed in turnkey project and serves primarily industrial customers. Another major disadvantage of such conventional systems is manual calibration. They also involve high costs to the tune of INR.3,000,000 (US$70,000) for 80 KW thermal power.

### BRIEF SUMMARY OF THE INVENTION

The invention in one embodiment features a system and a method for implementing a scalable heliostat array for use in solar-energy applications, including Solar-PV, Solar-Thermal, direct Solar-lighting, etc.

One component of the embodiment related to solar energy comprises of devices, called Orthogonal Trackers, to locate local sun-position operationally and accurately. Sun-position is determined by analyzing images of the Sun, obtained at the site. This eliminates all errors arising from estimating sun-position using sun-tracking formulae (open-loop). This information is conveyed to a plurality of small heliostats. The heliostats themselves are similarly equipped with sensing and/or imaging devices to locate targets very accurately. They are also capable of self-calibration, and self-testing. Specific low-cost and high-reliability designs are incorporated to address low-power control systems, and reliability with respect to dust, water/moisture/rain/dew, insects, small and large animals, wind, heat and sunlight, freezing, uncontrolled vegetation and creepers, etc.

Embodiments of the present invention also include applications to systems as diverse as, but not limited to, wide base-line radio telescopes, stereoscopic optical imaging, security systems camera mounts, automatic surveying instruments, maneuverable lighting, entertainment industry, sonar beamforming, etc.

These and other advantages of one or more aspects will become apparent from a consideration of the ensuing description and accompanying drawings.

### BRIEF DESCRIPTION OF THE SEVERAL VIEWS OF THE DRAWING

These features and aspects according to exemplary embodiments of the present invention will become better understood in reference to the following description, appended claims and accompanying drawings. The present invention is illustrated by way of example and not limitation in the figures of the accompanying drawing, and in which:

FIG. 1—Distributed Heliostat Array—is a diagrammatic illustration of one orthogonal tracker and two amongst a plurality of heliostats, and a target receiver for collecting and converting solar energy, in accordance with one exemplary embodiment.

FIG. 2—Orthogonal Tracker—is a diagrammatic illustration, in one exemplary embodiment, of the basic functionality of an Orthogonal Tracker. With two-axis tracking the Sun is tracked and located at the dead-center in the Image-Frame of the Orthogonal Tracker. This enables obtaining of accurate sun-position operationally, in real-time, in-situ.

FIG. 3—Control Scheme—indicates the overall control scheme, in accordance with one exemplary embodiment. One or more Master Controller(s) obtain information about sun-position from one or more Orthogonal Trackers and command a battery of smart heliostats to direct sun-light to one or more separate targets. All elements (including targets) communicate to one another via a communication network.

FIG. 4A—Sun's Image—shows Sun's image in the Image-Frame of an Orthogonal Tracker or a heliostat, according to one exemplary embodiment, and therefore the high resolution and precision with which sun-position may be obtained. Sun's disc subtends 0.5 degrees on Earth, so 0.5 degrees is made to correspond to many pixel width in an image-frame.

FIG. 4B—Tracking Sun—shows Sun's image in the Image-Frame of the Orthogonal Tracker or a self-calibrating heliostat, according to one preferred embodiment. Control systems ensure the centroid of the image is always held at the center of the Image-Frame.

FIG. 5A—Target—shows diagrammatically the image of a target in the Image-Frame of a heliostat. Sections of a receiver and the aperture to receive solar energy are imaged. The goal is to obtain the coordinates (θ and φ) of the target(s), in the reference frame of each heliostat.

FIG. 6—Heliostat Mechanism—shows diagrammatically in accordance with one exemplary embodiment, the possible nature of electromechanical control systems to enable designing of a distributed array of smart heliostats.

FIG. 7—Tilting of an axis in arbitrary direction by pulling strings along two orthogonal axes.

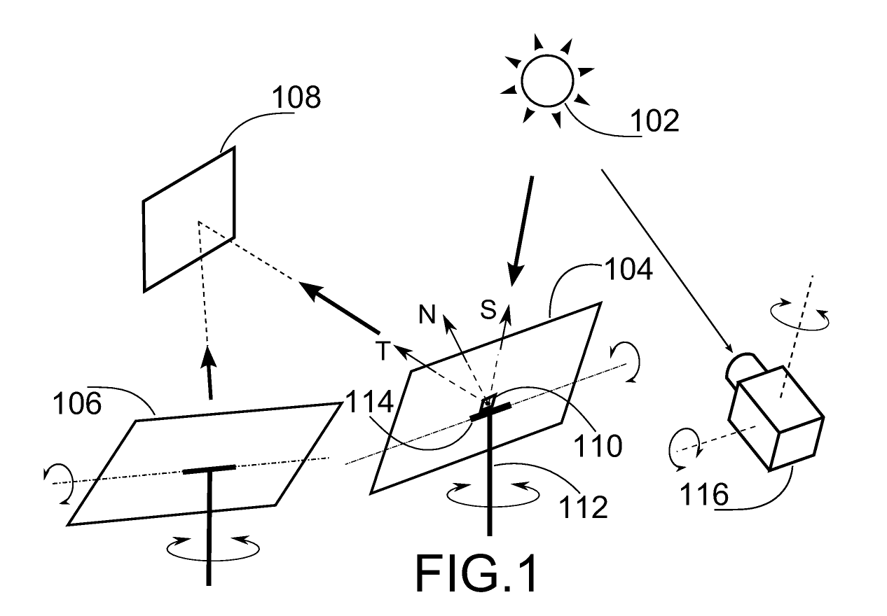

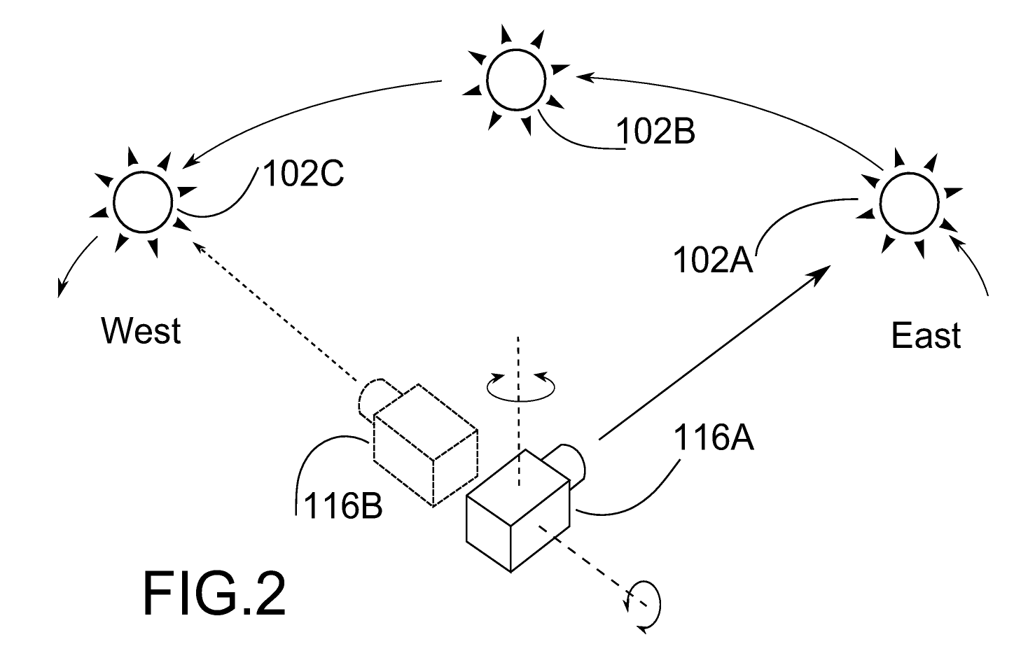

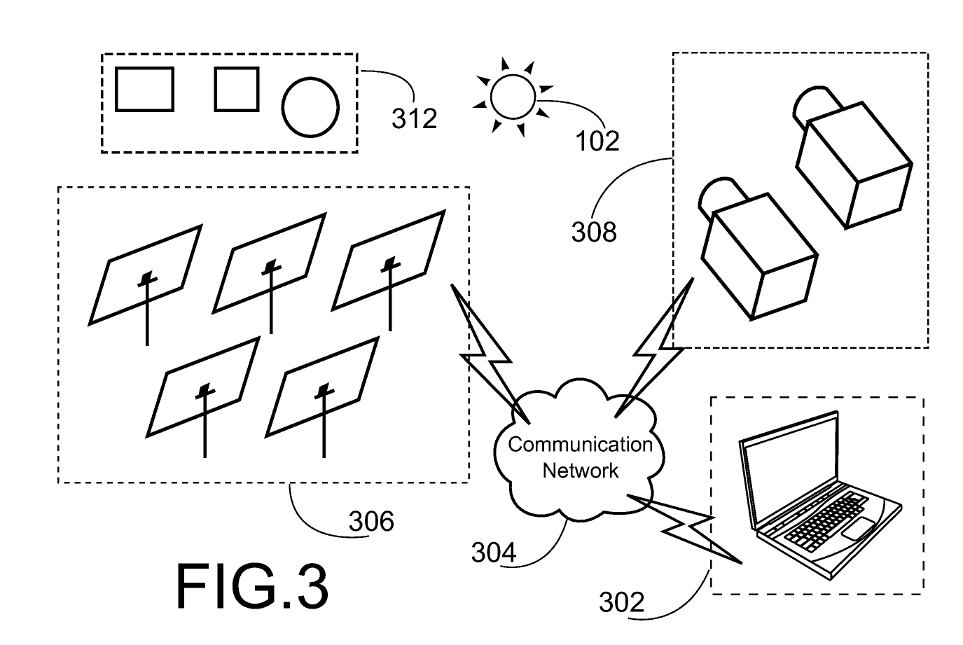

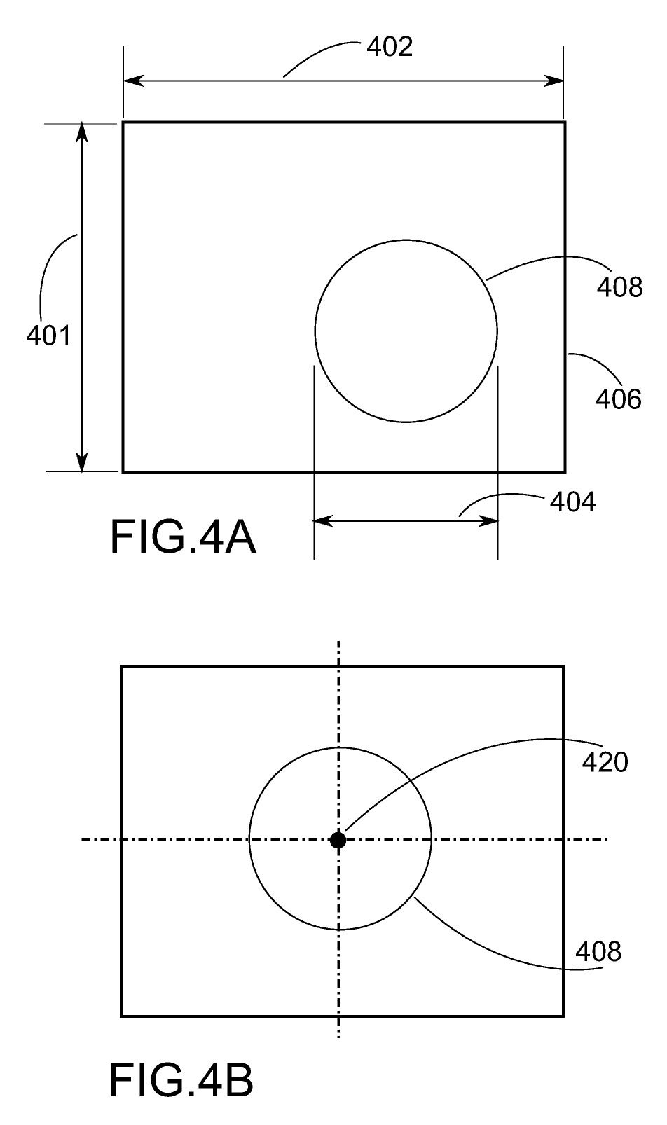

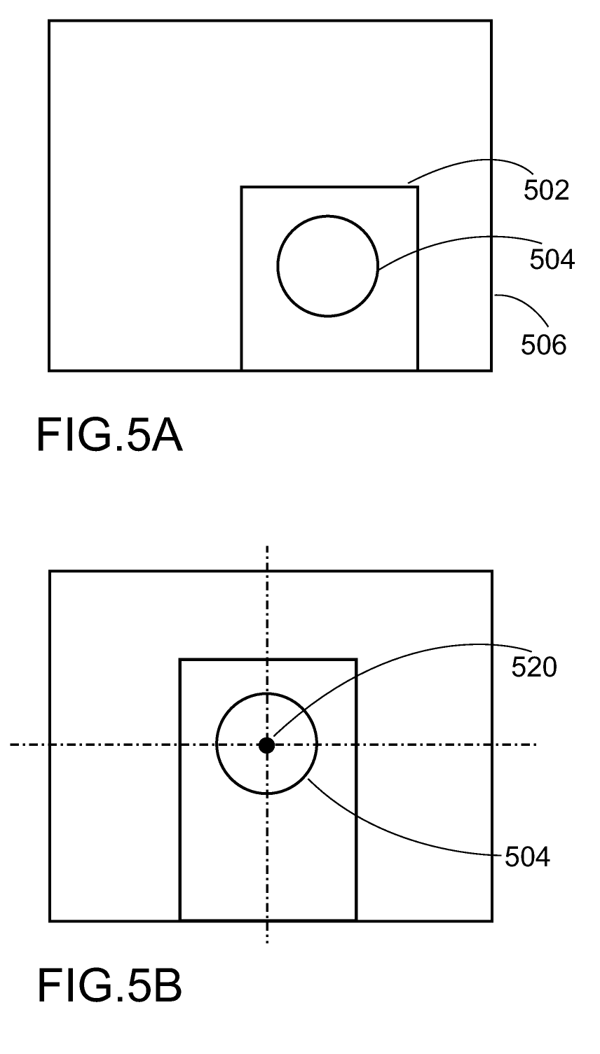

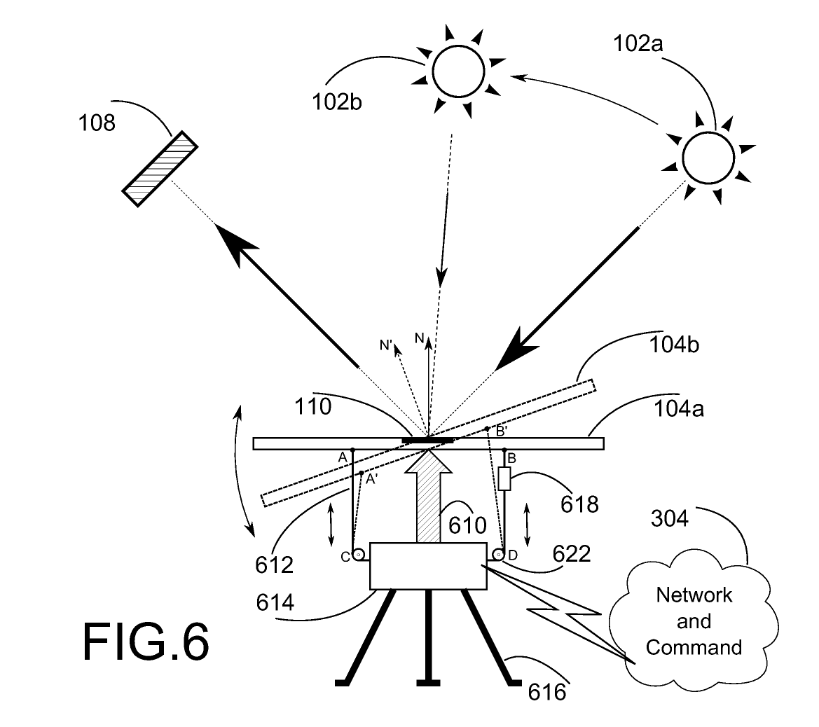

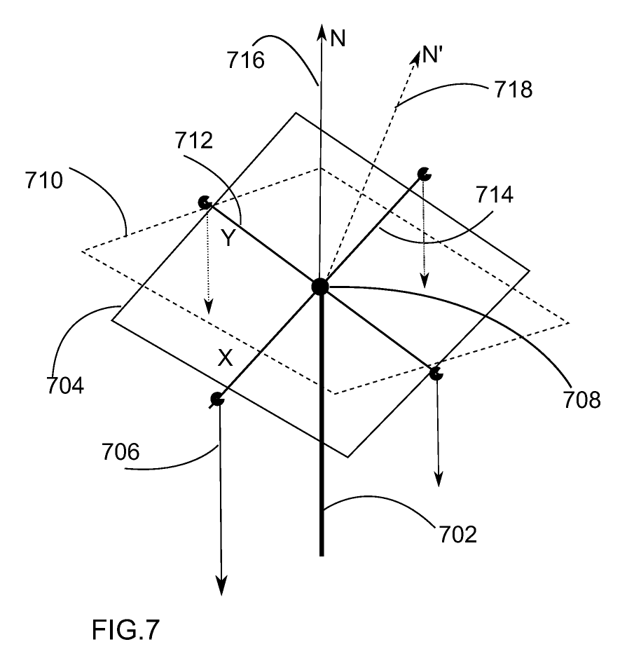

The following lists reference numerals for all the attached drawings:
102 Sun shining above heliostat field
104 Reflector/Heliostat 1
106 Reflector/Heliostat 2
108 Target or Collector of Solar Energy
FIG. 1:
110 Imaging Sensor on each Heliostat/Reflector's surface
112 First Axis of Reflector 1
114 Second Axis of Reflector 1
116 Orthogonal Tracker
102A Sun in East
102B Sun close to Noon
FIG. 2: 102C Sun in West
116A Orthogonal Tracker following Sun in East
116B Orthogonal Tracker continues to follow Sun in West
302 Master controller
304 Communication network
306 Array of smart heliostats directing solar energy to targets
FIG. 3:
308 One or more Orthogonal Trackers at site
102 Sun in heliostat field
312 One or more Targets/Receivers in a heliostat farm
401 Pixel height of Orthogonal Tracker's Image-Frame
402 Pixel width of Orthogonal Tracker's Image-Frame
FIG. 4A: 404 Diameter of Sun's image in pixels
406 Image-Frame of Orthogonal Tracker
408 Approximately circular blob of pixels is Sun's Image
420 Centroid of Sun's image positioned at Image-Frame center
FIG. 4B:
408 Sun's Image centered in Orthogonal Tracker's Image-Frame
502 Target's image in heliostat's Image-Frame
FIG. 5A: 504 Target's aperture in heliostat's Image-Frame
506 Heliostat's Image-Frame
520 Centroid of target's aperture in heliostat's camera field
FIG. 5B:
504 Target's image moved to center of heliostat's camera
602a Reflecting surface/mirror of smart heliostat at position ‘a’
602b Reflecting surface/mirror of smart heliostat at position ‘b’
102a Sun-position when reflector is at position ‘a’
102b Sun-position when reflector is at position ‘b’
108 Target/Receiver of solar energy
110 Light/imaging sensor and small solar-PV module
FIG. 6: 610 Pivot-like means to tilt reflector along two axes
612 String, timing-belt or other mechanism to move reflector
614 Processor, actuator and communication systems
616 Stands to erect and secure heliostat to any surface
618 Spring-like slack compensation element or device
304 Network to communicate with the heliostat
622 Pulleys and mechanical mechanisms to guide string/belt, etc.
702 Pivot axis
704 Surface element
706 String (only one segment shown)
708 Pivot
FIG. 7: 710 Tilted Surface element due to differential pull on X-strings
712 Y axis
714 X axis
716 Normal to surface element
718 Tilted Normal

### DETAILED DESCRIPTION OF THE INVENTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The following provides a working glossary for some of the more technical terms used in this document:
Azimuth-Elevation: Coordinates used to indicate any direction from a certain point on Earth's surface. Azimuth refers to the 360 degrees around a vertical line, and Elevation refers to the angle above the horizon.
Heliostat: Any device that helps to track the Sun. It could be of single axis to track only daily movement from east to west, or two axis to additionally track seasonal north-south movements.
Master-Slave: Control strategies where in a group of controllers, one or more enjoys a privileged status and are called Master controllers, and they have the ability to command ‘Slave’ controllers.
Open-Loop: When a control system is driven without any feedback, i.e. no self-correcting information is provided.
Orthogonal-Tracker: A device that tracks the Sun by looking at it directly at all times, and making necessary adjustments to continue to do so automatically.
Radian: Unit of angular measurement. 1 radian≈57 degrees.
Solar-position: The angular orientation of Sun with respect to any specified location on Earth's surface. It is typically specified as two angles, azimuth (φ) and tilt or elevation (θ).
Solar Power Tower: Large solar thermal installation, where a multitude of reflectors direct Sun's energy towards a central receiver, usually on a tower, to create megawatt scale power plants.
Solar-PV: Schemes to generate electricity using solar-cells.
Solar-Thermal: Schemes to utilize solar energy by changing it to heat. Subsequently steam turbines may be operated to generate electricity, or the heat directly utilized.
Topology: Relating to interconnection of various objects.

The following specification describes an embodiment of the invention. FIG. 1 illustrates the system view of different components of a distributed tracking solar collector. Such systems may be used in Solar Tower Power applications, for generation of electricity and other uses.

Both, the Orthogonal Tracker (116) and the heliostats (104 and 106) are capable of arbitrarily orienting themselves to any specified (θ, φ). This is called two-axis tracking, and is indicated in FIG. 1 by the two rotation-arrows on the respective axes (112 and 114 for heliostat 104). For purposes of clarity, only two heliostats are shown in a field that may be comprising of hundreds to hundreds of thousands of small heliostats.

Scaling laws dictate that cost of structures, as a function of size, increases as a power law. A size increase of two-fold could increase cost by more than a factor of two. Therefore it is preferable to replace one large reflector with several smaller reflectors. With mass-manufacturing techniques employed small reflectors can be manufactured with high-precision and at much lower cost.

Small reflectors are easy to transport and deploy. Self-calibration through a mechanism of collective intelligence and data harnessing, allows these light-weight systems to adapt to imprecise installations. Thus these units can be deployed rapidly and in large numbers, even on uneven and unconventional surfaces, including roof-tops, walls, cliffs, etc.

Small reflectors enjoy another significant advantage. Being physically close to ground surface, wind loading is less critical. Large heliostats have the problem of inaccuracies arising from wind-load related bending. In stronger winds, gusts and storms, large heliostats endure by using strong foundation and structural components. In one embodiment, injection-molded steel-mesh reinforced plastic parts can readily function. Also, since small units may also be deployed in large numbers, each in effect acts as a wind-shadow to the next. Overall wind loading advantages are very significant for small format heliostats.

FIG. 2 illustrates the basic operation of an Orthogonal Tracker. Sun appears to move across the sky, essentially from an east (102a) to west (102c) direction, following somewhat complex paths. Orthogonal trackers (116A) determine sun-position by ‘looking’ at the Sun directly at all times during the day. Since the control system has to re-orient itself to ensure that the Sun is always visible, the instrument effectively gathers information about sun-position.

FIG. 3 represents a field with a large number of small reflectors/heliostats (306). The entire system is orchestrated by “Master” (302) controller(s) on a network (304). Master(s) could therefore be located away from heliostat fields. Each reflector is directed to reflect sunlight to specified target(s) (312), accurately.

In addition to using various sun-tracking formulae to determine Sun's position, this embodiment accurately determines position of Sun (102) through direct measurements. The device used is an Orthogonal Tracker (116). By position is meant the angular measure (θ,φ), where θ (theta) being the elevation, and φ (phi) the azimuthal angle that Sun subtends at the heliostats locally. Sun-position so obtained is communicated on a network (304) to a plurality of small heliostats (306), in real-time.

In one embodiment of the invention, an image-sensor/camera (110) is located on the heliostats. The optical axis of the image-sensor or camera is substantially aligned with the vector normal (N) to the reflective surface. In some embodiments the tracking controller orients the camera to calibrated reference points and data so obtained is analyzed to provide correction terms. So any deviation between the mirror normal and the optical axis of the camera, or tilt in heliostat frame, can be compensated.

In another embodiment of the invention, in the calibration process, heliostats scan and locate the position of targets. Images obtained with on-board camera (110) are used to locate target(s) precisely (FIG. 5A/5B). The target coordinates so obtained are saved for future reference.

With both, sun-position and target-position known to each heliostat, it orients its normal (N) to bisect the angle between the Sun and the target. This ensures that sunlight will be reflected to the target(s) from each heliostat independently, automatically, and continuously. The result is concentration of solar energy at the target (108).

In another embodiment of the invention, more than one Orthogonal Tracker may be deployed (308) to increase reliability and accuracy of the system (FIG. 3).

This method of control is different from conventional systems where sun-position is determined by various sun-tracking formulae, and is essentially open-loop. Sun-tracking formulae cannot take into account many random fluctuations, including atmospheric refractive index changes due to temperature and pressure variations. So their use in sun-tracking is plagued with difficulties. The use of Orthogonal Trackers to obtain sun-position operationally circumvents this problem.

In one embodiment, an Orthogonal Tracker has a high-resolution digital camera. As shown in FIG. 4A, appropriate lens/optics are configured to have the Sun's image captured as a nearly circular blob of pixels (408) with a certain diameter (404). Suitable neutral-density filters are used (not shown) to ensure the camera sensors are not saturated. The image sensor has sufficient rows (401) and columns (402) to accommodate Sun's image. Sun subtends an angle of approximately 0.5 degrees on Earth's surface. For illustrative purposes, we consider an Image-Frame (406) having resolution of 300 pixel×300 pixel, and the circular blob of Sun's image having width of 100 pixels. Thus each pixel width in the image frame corresponds to 0.5 degrees/100, or we effectively have tracking resolution of 0.005 degrees. With present generation high-resolution digital cameras and image-sensors it is possible to go to much higher resolution and track the Sun in real-time.

As shown in FIG. 4B, the Orthogonal Tracker re-orients itself periodically, so that the centroid of Sun's image (420) is positioned at the center of the Image-Frame. The mathematical evaluation of the centroid can be done with minimal errors. Thus, very high accuracy sun-position is determined by this apparatus and method.

One embodiment of a small heliostat is shown in FIG. 6. A reflecting surface (104) is substantially balanced on a pivotable structure (610). For clarity, only one of the two tilting axes is illustrated. A pivotable structure is readily tilted (104a to 104b) with small differential force, not unlike a conventional weighing balance. So, a properly designed control system (614) can operate from low power, and which can be provided by a small Solar-PV panel (110) or from outside and coupled through the pivotal structure (610), or from stored energy on the reflecting surface element (104). Conservative estimates, only for illustration, and not as a limitation, go as follows: A 1 kg force moving over 1 meter over the course of 6 hours implies average power requirement of less than 1 milli-Watt. Even a small solar panel can provide power in excess of this. So suitable low-power designs are incorporated. To achieve accuracy, zero backlash tilt mechanisms are implemented in this embodiment by means of a cable/string/chain/belt/timing-belt (612) or any other means to pull, and running over pulleys/gears/rollers/cams (622) or other similar guiding elements. The control system (614) comprising of no-slip mechanism to pull the “string”. It may also have mechanisms to make the panel return to “home” position after sunset, with energy saved within the unit. The energy-storage means could be a mechanical spring, weights pulled against gravity, electrical or chemical storage, etc.

In one embodiment the control system (614) can be on the reflecting surface side of the pivotal structure. Although the surface (104) can tilt along any direction, the mechanisms of the pivotal structure do not allow the surface to spin or oscillate about the pivot-axis. The small format heliostat can be rapidly deployed and mounted on uneven surfaces by simply pegging its legs (616).

In one method of calibration, post deployment, or whenever appropriate “Masters” direct it to do so, the heliostat of FIG. 6 starts to track the Sun not unlike an Orthogonal Tracker. In the meantime, information about actual sun-position is also simultaneously available from local Orthogonal Trackers on the network. By comparison, the heliostat will be able to estimate its own orientation, tilt and misalignment. Keeping a record of these information will allow it to make suitable compensation when trying to reflect sunlight (102) towards targets (108).

FIG. 5A and FIG. 5B illustrate, in one embodiment, how smart reflectors and heliostats are able to also determine coordinates of the target/receiver(s). The on-board image sensor (110) can capture images of the target (502 and 504), not unlike an Orthogonal Tracker imaging the Sun. The Image-Frame (506) is suitably configured to capture and show images of the target (504). Such captured images may be analyzed manually, or automatically, and the location of target's centroid (520) determined. Since each pixel coordinate also translates to an equivalent internal coordinate indicating a reflector's tilt-state, the position of the target is accurately determined.

Another advantage of a Master-Slave topology for heliostat operation in a large deployment (hundreds of thousands) of heliostats is the ability to service the entire system. The small, smart reflectors can report their state of “health” to supervisory Masters. Should any particular heliostat need servicing, not only can it indicate so automatically to the Master, but it can also allow a replacement for it to start functioning right away. Without automatic assessment in a Master-Slave topology, maintenance of a large system would be a problem.

So this embodiment illustrates a method of Master-Slave control implemented with rapidly deployable small heliostats. This can allow arbitrarily large arrays of heliostats to perform in a coherent, intelligent and accurate way to reflect solar energy into a configuration of targets.

Another embodiment of the invention is in the field of enhanced energy harnessing from Solar-PV panels. Small format, energy lean and autonomous heliostats are equally important in Solar-PV power generation. Power output of a Solar-PV panel can increase up to 40% or more using two-axis tracking. Reduced investment in procuring solar panels and real-estate cost (commitment to land and cost to make robust mounting) makes a two-axis tracker based solutions viable.

Tilting mechanism, similar to ones described in FIG. 6 can be used for orienting Solar-PV panels. Instead of the reflecting surface, (104) represents the surface of a Solar-PV panel. Designs are simplified since there is no need for a captive solar cell. A small fraction of the power from the PV panel itself could drive the entire control system (614).

The solar panel itself also acts as an energy sensor (110). Measuring power output from the panel, and orienting to achieve maximum power output, provides a simple mechanism to control the system.

In another embodiment of Solar-PV application, the smart heliostats do not need to be connected on a network either. Each panel simply has all the inputs necessary to orient itself. This could provide for even lower cost to implement the heliostats for tilting Solar-PV panels.

Since the small format heliostats described herein are completely self-adjusting and based on feedback control, there will be less need for strong and robust foundation for solar-PV mounting. This would mean additional savings of cost for any installation.

In embodiments featuring the option of a “Master-Slave” architecture, there are distinct advantages. The ability to report the state of “health” of a particular panel in a large array of hundreds of thousands of panels in a solar-PV farm would be a daunting task without the use of smart heliostats described herein. Accurate profiling of power-harnessing, load-balancing, over-loading, fault-conditions, service need, etc., may all be coordinated by means of the network.

Another embodiment of the invention relates to direct use of reflected sunlight for day-time illumination of interiors of buildings using automatically steering small heliostats. Large number of urban buildings, such as offices, malls, hospitals, factories, etc., have a huge number of inefficient and heat generating lamps, working within air-conditioned environment. By channeling sunlight into the buildings, not only will it allow reduction in direct illumination energy cost, but also large reduction in cooling bills. In addition, cost of maintenance of electrical infrastructure can be significantly reduced.

The small format autonomous and smart heliostats in a master-slave configuration will allow a multitude of small mirrors to direct their light into many different inlets into buildings (say windows, doors, balconies, etc.).

Low maintenance and low cost steering mechanisms as described in FIG. 6 can function as sunlight reflectors. Robust steerable mechanisms discussed herein can allow guiding of sunlight.

Orthogonal Tracking establishes local sun-coordinates. Small mirror-like reflectors in a distributed array can be used to direct sunlight to a multitude of receivers. Unlike solar thermal applications, where many heliostats direct energy to the same target, in sunlight based illumination, the targets are numerous.

Master-Slave topology will allow fine control and tuning of the illumination requirements of a particular building.

Another embodiment of the invention is useful in the field of direct solar heating. There are many applications of heating requirements which are not directly related to electricity generation. Direct control of a battery of distributed reflectors can lead to sophisticated control systems, such as temperature control of an oven or dryer. The networked reflectors can be made to switch in and out to deliver energy to a particular target.

The ability to collect large quantity of solar energy inexpensively leads to a large number of applications:
Industrial heating: In plastic industry, diary industry, etc.
Agriculture: Operations like drying, boiling, roasting, etc.
Civil construction: Accelerated curing of concrete, etc.
Sea-water desalination: Vast coastal regions can benefit from direct desalination of sea-water. Added by-product will be electricity and minerals like salt.

While the above description contains many specificities, these should not be construed as limitations on the scope, but rather as an exemplification of one (or several) preferred embodiment thereof. Many other variations are possible.

For example there are many other applications of an inexpensive and robust tilting mechanism as discussed in FIG. 6. When used singly or in large orchestrated arrays on a network and remotely activated, monitored and controlled, in a Master-Slave topology (as discussed in FIG. 3), can lead to many dramatic applications including:
Radio Telescopy: A large array of small steerable receivers (dipoles) spread over substantial distances, can also implement a large-aperture radio-telescope with high resolution. VLBI (Very Long Baseline Interferometry) provides mechanisms to achieve high-resolution radio-images of the sky (en.wikipedia.org/wiki/Radio_telescope), and with elements of the array located even a thousand kilometers apart.
Synthesized Optical Telescope: Requires a distributed array of reflectors that may be controlled to produce effectively a very large optical telescope, that is steer-able, and with large resolution (en.wikipedia.org/wiki/Astronomical_interferometer).
Security Systems: Steer-able slave units containing cameras can readily adapt to a variety of surveillance and security cameras.
Entertainment Industry: Steer-able mechanisms under remote control for stage-lighting, art gallery lighting, etc.

Accordingly, the scope should be determined not by the embodiment(s) illustrated, but by the appended claims and their legal equivalents.

The above-described systems and methods can be implemented in digital electronic circuitry, in computer hardware, firmware, and/or software. The implementation can be as a computer program product (i.e., a computer program tangibly embodied in an information carrier). The implementation can, for example, be in a machine-readable storage device, for execution by, or to control the operation of, data processing apparatus. The implementation can, for example, be a programmable processor, a computer, and/or multiple computers.

A computer program can be written in any form of programming language, including compiled and/or interpreted languages, and the computer program can be deployed in any form, including as a stand-alone program or as a subroutine, element, and/or other unit suitable for use in a computing environment. A computer program can be deployed to be executed on one computer or on multiple computers at one site.

Method steps can be performed by one or more programmable processors executing a computer program to perform functions of the invention by operating on input data and generating output. Method steps can also be performed by and an apparatus can be implemented as special purpose logic circuitry. The circuitry can, for example, be a FPGA (field programmable gate array) and/or an ASIC (application specific integrated circuit). Modules, subroutines, and software agents can refer to portions of the computer program, the processor, the special circuitry, software, and/or hardware that implements that functionality.

Processors suitable for the execution of a computer program include, by way of example, both general and special purpose microprocessors, and any one or more processors of any kind of digital computer. Generally, a processor receives instructions and data from a read-only memory or a random access memory or both. The essential elements of a computer are a processor for executing instructions and one or more memory devices for storing instructions and data. Generally, a computer can include, can be operatively coupled to receive data from and/or transfer data to one or more mass storage devices for storing data (e.g., magnetic, magneto-optical disks, or optical disks).

Data transmission and instructions can also occur over a communications network. Information carriers suitable for embodying computer program instructions and data include all forms of non-volatile memory, including by way of example semiconductor memory devices. The information carriers can, for example, be EPROM, EEPROM, flash memory devices, magnetic disks, internal hard disks, removable disks, magneto-optical disks, CD-ROM, and/or DVD-ROM disks. The processor and the memory can be supplemented by, and/or incorporated in special purpose logic circuitry.

To provide for interaction with a viewer, the above described techniques can be implemented on a computer having a display device. The display device can, for example, be a cathode ray tube (CRT) and/or a liquid crystal display (LCD) monitor. The interaction with a viewer can, for example, be a display of information to the viewer and a keyboard and a pointing device (e.g., a mouse or a trackball) by which the viewer can provide input to the computer (e.g., interact with a viewer interface element). Other kinds of devices can be used to provide for interaction with a viewer. Other devices can, for example, be feedback provided to the viewer in any form of sensory feedback (e.g., visual feedback, auditory feedback, or tactile feedback). Input from the viewer can, for example, be received in any form, including acoustic, speech, and/or tactile input.

The above described techniques can be implemented in a distributed computing system that includes a back-end component. The back-end component can, for example, be a data server, a middleware component, and/or an application server. The above described techniques can be implemented in a distributing computing system that includes a front-end component. The front-end component can, for example, be a client computer having a graphical viewer interface, a Web browser through which a viewer can interact with an example implementation, and/or other graphical viewer interfaces for a transmitting device. The components of the system can be interconnected by any form or medium of digital data communication (e.g., a communication network). Examples of communication networks include a local area network (LAN), a wide area network (WAN), the Internet, wired networks, and/or wireless networks.

The system can include clients and servers. A client and a server are generally remote from each other and typically interact through a communication network. The relationship of client and server arises by virtue of computer programs running on the respective computers and having a client-server relationship to each other.

The communication network can include, for example, a packet-based network and/or a circuit-based network. Packet-based networks can include, for example, the Internet, a carrier Internet protocol (IP) network (e.g., local area network (LAN), wide area network (WAN), campus area network (CAN), metropolitan area network (MAN), home area network (HAN)), a private IP network, an IP private branch exchange (IPBX), a wireless network (e.g., radio access network (RAN), 802.11 network, 802.16 network, general packet radio service (GPRS) network, HiperLAN), and/or other packet-based networks. Circuit-based networks can include, for example, the public switched telephone network (PSTN), a private branch exchange (PBX), a wireless network (e.g., RAN, bluetooth, code-division multiple access (CDMA) network, time division multiple access (TDMA) network, global system for mobile communications (GSM) network), and/or other circuit-based networks.

The communication device can include, for example, a computer, a computer with a browser device, a telephone, an IP phone, a mobile device (e.g., cellular phone, personal digital assistant (PDA) device, laptop computer, electronic mail device), and/or other type of communication device. The browser device includes, for example, a computer (e.g., desktop computer, laptop computer) with a world wide web browser (e.g., Microsoft® Internet Explorer® available from Microsoft Corporation, Mozilla® Firefox available from Mozilla Corporation). The mobile computing device includes, for example, a personal digital assistant (PDA).

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While the present invention has been described in connection with the preferred embodiments of the various figures, it is to be understood that other similar embodiments may be used or modifications or additions may be made to the described embodiment for performing the same function of the present invention without deviating therefrom. Therefore, the present invention should not be limited to any single embodiment, but rather construed in breadth and scope in accordance with the recitation of the appended claims.

What is claimed is:

1. A system for directing incident solar radiation to one or more predetermined targets, the system comprising:
(a) one or more orthogonal trackers to measure local sun-position,
(b) one or more heliostats with a reflecting surface having an optical axis and an image-sensor substantially aligned along said optical axis, wherein the heliostats are configured to:
i. respond to commands from a master controller,
ii. determine said targets position,
iii. self-calibrate its own orientation and tilt axis,
(c) said master controller connected to said orthogonal tracker and said heliostats on a network, wherein said master controller is configured to:
i. receive sun-position from said orthogonal tracker and communicate the same to said heliostats,
ii. determine said targets,
iii. optimize and control all slaves

2. The system of claim 1, wherein at least one of the orthogonal trackers comprises:
(a) tracking means for multiple axis movement,
(b) imaging means with suitable optics to image the Sun and
(c) communication means with master controller.

3. The system of claim 1, wherein, for the orthogonal trackers special adaptors are provided for use in telescopy or astronomy.

4. The system of claim 2, wherein, for the orthogonal trackers special adaptors are provided for use in telescopy or astronomy.

5. A system as of claim 1, wherein, at least one of the heliostats comprises:
(a) a surface element,
(b) supporting means for pivot mechanism to allow arbitrary orientation of said surface element,
(c) an image-sensor mounted on said surface element with its optical axis substantially aligned with the normal to said surface element,
(d) low power means for a tracking controller that can communicate with master controllers,
(e) pulling means for tilting said surface element about said pivot mechanism,
(f) erecting means to secure the heliostat to ground,

6. The system of claim 5, wherein a reflecting mirror is the surface element, to reflect solar or optical energy to a variety of targets.

7. The system of claim 5 wherein a solar photo-voltaic panel is the surface element, to directly generate electricity.

8. The system of claim 5 wherein a small size mirror is used for providing direct solar lighting.

9. A method for arbitrarily orienting a pointing vector in a half-space, comprising of the steps of:
(a) providing reference frames such that said half-space comprises of azimuthal angle φ to assume any value and elevation angle θ to assume values in the range [0, 90°] where θ=0° is identified as vertical,
(b) providing a pivot axis which is substantially aligned along said vertical,
(c) providing a surface element which intersects said pivot axis and where the point of intersection is identified as the pivot,
(d) identifying two substantially orthogonal axes X and Y in said surface element which intersect at the pivot,
(e) attaching strings, cables or couplings, to two points along said X axis on opposite sides of said pivot and equidistant from said pivot to provide tilting motion to said surface element about said Y axis by exercising differential pull on said strings, cables or couplings,
(f) similarly attaching strings to two points along said Y axis on opposite sides of said pivot and equidistant from said pivot to provide tilting motion to said surface element about said X axis,
(g) providing means to prevent torsional movement of said surface element about said axis, and
whereby the action of pulling on both sets of said strings, cables or couplings will allow one to re-orient the normal to said surface element at said pivot to point along any predetermined direction within said half-space.

10. A method to measure sun-position precisely and automatically in real-time, comprising of the steps of:
(a) providing a substantially high-resolution image-sensor
(b) providing suitable optics for said image-sensor to view the Sun,
(c) providing a smart angular orienting system to which said image-sensor is mounted,
(d) step and repeat said angular orienting system to survey the sky, and
(e) stop surveying when image of Sun shows substantially in the image-frame of said image-sensor,
(f) continuously evaluate centroid of Sun's image,
(g) evaluate and note movement of centroid per unit time,
(h) continue to step said angular orienting system so Sun's image is approximately re-positioned at the center of image-frame,
(i) calibrate angular step size of said angular orienting system by noting corresponding shift in image in pixel units,
(j) noting that Sun subtends about 0.5° on Earth
whereby very precise movement of Sun is determined by noting that each pixel movement of the centroid corresponds to 0.5° divided by pixel width of Sun's diameter.
